(19) United States
(12) Patent Application Publication
(10) Pub. No.: US 2009/0166844 A1
(43) Pub. Date: Jul. 2, 2009

(54) METAL COVER ON FLIP-CHIP MATRIX-ARRAY (FCMX) SUBSTRATE FOR LOW COST CPU ASSEMBLY

(76) Inventor: Xuejiao Hu, Phoeniz, AZ (US)

Correspondence Address: INTEL CORPORATION;c/o CPA Global, P.O. BOX 52050, MINNEAPOLIS, MN, 55402, US

(21) Appl. No.: 11/964,401

(22) Filed: Dec. 26, 2007

(51) Int. Cl. H01L 23/488; H01L 21/58

(52) U.S. Cl. 257/693; 438/114; 257/E23.023; 257/E21.505

(57) ABSTRACT

In some embodiments, a metal cover on flip-chip matrix-array (FCMX) substrate for low cost CPU assembly is presented. In this regard, an apparatus is introduced comprising a plurality of integrated circuit dice coupled with a substrate, a thermal interface material on top surfaces of the dice, and a metal plate on top of the thermal interface material on top of the dice. Other embodiments are also disclosed and claimed.

### FIELD OF THE INVENTION

Embodiments of the present invention generally relate to the field of integrated circuit packages, and, more particularly to a metal cover on flip-chip matrix-array (FCMX) substrate for low cost CPU assembly.

### BACKGROUND OF THE INVENTION

Flip-chip matrix-array (FCMX) packaging, where a plurality of integrated circuit devices are attached to a substrate and then singulated, may offer advantages for cost savings. The problems presented, however, include warpage of the substrate and heat dissipation from the die.

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a cross-sectional view of partially formed IC packages, in accordance with one example embodiment of the invention;

FIG. 2 is a graphical illustration of a cross-sectional view of partially formed IC packages, in accordance with one example embodiment of the invention;

FIG. 3 is a graphical illustration of a cross-sectional view of separated IC packages, in accordance with one example embodiment of the invention; and

FIG. 4 is a flow chart of an example method for CPU assembly, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a cross-sectional view of partially formed IC packages, in accordance with one example embodiment of the invention. In accordance with the illustrated example embodiment, package assembly 100 includes one or more of substrate 102, integrated circuit (IC) dice 104, thermal interface layers 106, metal cover 108, substrate cut-lines 110, and metal cover cut-lines 112.

Substrate 102 represents a substrate designed to receive integrated circuit dice 104 and transmit signals to electrical connections on a backside of substrate 102 opposite die 104. In one embodiment the backside of substrate 102 contains ball grid array (BGA) connections (not shown). In another embodiment, the backside of substrate 102 contains land grid array (LGA) connections.

IC dice 104 represent any type of integrated circuit devices, such as, for example processors, controllers, memories, transceivers, and the like. IC dice 104 may be flip-chip attached to substrate 102. In one embodiment, IC dice 104 have a thickness of about 125 micrometers.

Thermal interface layers (TIM) 106 provide thermal contacts and heat conductivity between IC dice 104 and metal cover 108. In one embodiment, TIM 106 represents a solder TIM. In another embodiment, TIM 106 represents a polymer TIM.

Metal cover 108 represents a metal sheet to provide stability and thermal conductivity to the IC packages. In one embodiment, metal cover 108 represents aluminum. In another embodiment, metal cover 108 represents copper. Metal cover 108 may have a thickness in the range of from about 200 to about 1800 micrometers.

Substrate cut-lines 110 and metal cover cut-lines 112 represent lines where cutting will occur to singulate the IC device packages. In one embodiment, substrate cut-lines 110 and metal cover cut-lines 112 are partially precut before assembly. In one embodiment, cut-lines 110 and 112 include intermittent cuts through the materials. In another embodiment, cut-lines 110 and 112 include cuts partially through the materials.

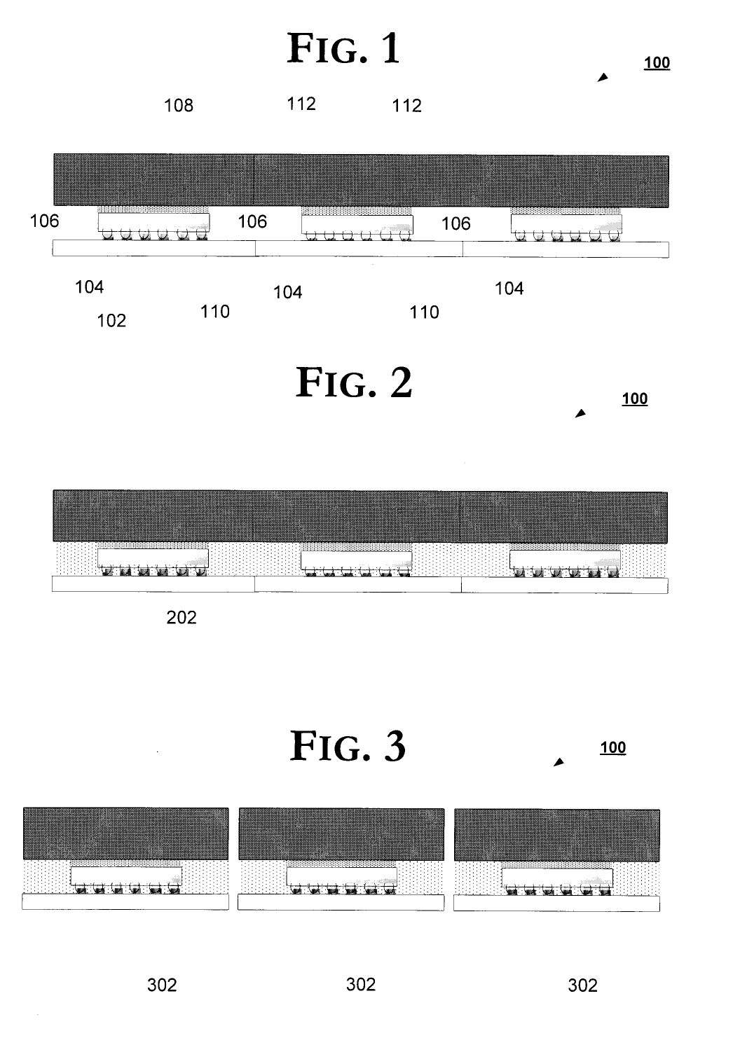

FIG. 2 is a graphical illustration of a cross-sectional view of partially formed IC packages, in accordance with one example embodiment of the invention. As part of a process for CPU assembly, for example as described in reference to FIG. 4, adhesive 202 is filled in the gaps between metal cover 108 and substrate 102 near integrated circuit devices 104.

Adhesive 202 may be chosen for its ability to flow into gaps and also for its ability to harden and provide mechanical support against warpage.

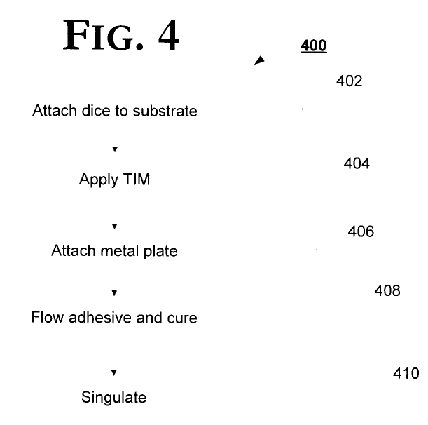

FIG. 3 is a graphical illustration of a cross-sectional view of separated IC packages, in accordance with one example embodiment of the invention. As shown, cutting has occurred along cut-lines 10 and 112 forming separate IC device packages 302. In one embodiment, cutting is done with a saw. In another embodiment, a water jet is used to separate IC device packages 302.

IC device packages 302 may undergo further processing or assembly before being integrated into an electronic device or appliance, such as a laptop, desktop, handheld or other device.

FIG. 4 is a flow chart of an example method for CPU assembly, in accordance with one example embodiment of the invention. It will be readily apparent to those of ordinary skill in the art that although the following operations may be described as a sequential process, many of the operations may in fact be performed in parallel or concurrently. In addition, the order of the operations may be re-arranged or steps may be repeated without departing from the spirit of embodiments of the invention.

According to but one example implementation, the method of FIG. 4 begins with attaching (402) dice 104 to substrate 102. In one embodiment, more than 12 IC dice 104 are attached to a single substrate 102.

Next, TIM 106 is applied (404) on top of IC dice 104. In one embodiment, TIM 106 has a thickness of about 200 micrometers when applied.

Next, metal cover 108 is attached (406) on top of TIM 106. In one embodiment, metal cover 108 is placed on TIM 106 and pressed, thereby compressing TIM 106 to a thickness of about 50 micrometers.

Next, adhesive 202 is flowed and cured (408) between substrate 102 and metal cover 108.

Lastly, the assembly is singulated (410) to form separate IC device packages 302. In one embodiment, singulation may involve a saw. In another embodiment, singulation may involve a water jet. Additional steps may be needed to complete the packages before they can be placed in an electronic device.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An apparatus comprising:
a plurality of integrated circuit dice coupled with a substrate;
a thermal interface material on top surfaces of the dice; and
a metal plate on top of the thermal interface material on top of the dice.

2. The apparatus of claim 1, further comprising an adhesive material substantially filling gaps between the metal plate and the substrate.

3. The apparatus of claim 1, wherein the metal plate is at least partially precut around individual dice.

4. The apparatus of claim 1, wherein the substrate is at least partially precut around individual dice.

5. The apparatus of claim 1, wherein the metal plate comprises a metal chosen from the group consisting of aluminum and copper.

6. The apparatus of claim 1, further comprising ball grid array (BGA) connections on a backside of the substrate.

7. The apparatus of claim 6, wherein the thermal interface material (TIM) comprises a solder TIM.

8. The apparatus of claim 7, wherein the thermal interface material (TIM) comprises a polymer TIM.

9. A method comprising:
attaching integrated circuit dice to a substrate;
applying a thermal interface material (TIM) on the integrated circuit dice; and
placing a metal plate on the TIM.

10. The method of claim 9, further comprising flowing adhesive into gaps between the metal plate and the substrate.

11. The method of claim 9, further comprising singulating the integrated circuit dice.

12. The method of claim 9, wherein applying a thermal interface material (TIM) on the integrated circuit dice comprises applying a solder TIM on the integrated circuit dice.

13. The method of claim 9, wherein applying a thermal interface material (TIM) on the integrated circuit dice comprises applying a polymer TIM on the integrated circuit dice.

14. The method of claim 9, wherein placing a metal plate on the TIM comprises placing a plate of metal chosen from the group consisting of aluminum and copper.

15. The method of claim 9, wherein placing a metal plate on the TIM comprises placing a metal plate that has been at least partially precut on the TIM.
